(19) United States
(12) Patent Application Publication
(10) Pub. No.: US 2006/0201589 A1
(43) Pub. Date: Sep. 14, 2006

(54) Components comprising metallic material, physical vapor deposition targets, thin films, and methods of forming metallic components

(75) Inventors: Diana L. Morales, Veradale, WA (US); Susan D. Strothers, Spokane, WA (US)

Correspondence Address: WELLS ST. JOHN P.S., 601 WEST FIRST AVE, SUITE 1300, SPOKANE, WA, 99201, US

(73) Assignee: Honeywell International Inc.

(21) Appl. No.: 11/286,636

(22) Filed: Nov. 23, 2005

Related U.S. Application Data
(60) Provisional application No. 60/661,292, filed on Mar. 11, 2005.

(51) Int. Cl. C23C 14/00; C22C 27/04; B22F 3/15; C22C 27/06

(52) U.S. Cl. 148/423; 204/298.13; 419/49

(57) ABSTRACT

The invention includes components containing metallic material. The metallic material can be comprised of a plurality of grains, with substantially all of the grains being substantially equiaxial, and the grains having an average grain size of less than or equal to about 30 microns. The components can be formed by utilization of a uniaxial vacuum hot press together with a starting metallic powder characterized by 325 mesh size. An exemplary component is a sputtering target having a high degree of uniformity across its sputtering face as well as throughout its thickness.

### RELATED PATENT DATA

This application is related to U.S. provisional application 60/661,292, which was filed Mar. 11, 2005.

### TECHNICAL FIELD

The invention pertains to components comprising metallic materials, physical vapor deposition (PVD) targets, thin films comprising high uniformity, and methods of forming metallic components.

### BACKGROUND OF THE INVENTION

It can be desired to form metallic components having high purity, high microstructural uniformity, and small uniform grain size throughout. Such components can be desirable as, for example, physical vapor deposition targets.

High microstructural uniformity, high purity, and small equiaxed grain size of PVD targets can improve the uniformity with which thin films are sputter-deposited from the targets onto substrates during PVD processes. For instance, improved thin films can be formed during sputter deposition of metallic materials onto semiconductor wafer substrates if a target utilized during the sputter deposition process has high uniformity, high purity, and relatively small grain size, as compared to thin films which would be formed from targets having less uniformity, lower purity and/or larger grain size.

An exemplary material which can be sputter-deposited is molybdenum. For instance, molybdenum is utilized as an electrode in bulk acoustic wave resonators (BAWs), surface acoustic wave filters (SAWs), and film bulk acoustic resonators (FBARs). Such acoustic wave resonators and filters can be utilized for numerous so-called wireless applications, including, for example, applications in cell phones and WiFi devices.

Exemplary of the acoustic wave devices and acoustic filter devices discussed above is FBAR filter technology. Such is based on thin films of piezoelectrically active materials, such as, for example, aluminum nitride and zinc oxide, and of electrode materials, such as, for example, aluminum and molybdenum.

In resonator applications, frequency control can be highly important. FBAR resonator frequencies are set by the thickness of the piezoelectric and electrode films, which are desirably accurate to 0.2%. Thus, it is desired for the molybdenum thin films utilized in acoustic wave resonators and filters to have very tight tolerances of uniformity. The high film thickness tolerances desired for acoustic wave resonator applications can be, for example, between 0.5% at 1 sigma and 1% at 3 sigma, which can be a more rigid uniformity tolerance than the tolerances of typical semiconductor film applications.

Conventional molybdenum sputtering targets tend to produce films with uniformity outside of desired tolerances, and further tend to have undesired low target life due to, in part, large grains in the microstructure of the targets. It is well established that magnetron sputtering targets can erode non-uniformly if the microstructure within the targets is inconsistent, which can lead to non-uniformity in films formed from the targets.

It is desired to develop methods of forming metallic components, (such as, for example, sputtering targets) having high microstructural uniformity, high purity and/or small grain size. It is further desired that such components be suitable for various applications, including, for example, sputter-deposition of thin metallic films utilized in semiconductor devices. Exemplary devices can include radiofrequency (Rf) micro-electro-mechanical systems (MEMS) such as, for example, BAWs, SAWs and FBARs.

In further aspects of the prior art, physical vapor deposition can be utilized in numerous semiconductor fabrication applications. For instance physical-vapor-deposited ruthenium and/or tantalum can be utilized in various barrier materials (for instance, in compositions utilized as barriers to copper diffusion), and/or as substrates for seedless plating of copper. Additionally, or alternatively, physical vapor deposited materials can be incorporated into capacitors, transistor gates, or any of numerous other devices incorporated into integrated circuitry.

### SUMMARY OF THE INVENTION

In one aspect, the invention includes a method for controlling starting particle size and conditions utilized for forming a sputtering target, with such conditions being chosen to be suitable for forming a target having a fine uniform structure and capable of sputter-depositing a uniform film throughout the life of the target. Methodology utilized to form the target can include utilization of a powder having a powder size of less than or equal to about 325 mesh, which is pressed and sintered using a uniaxial vacuum hot press to form a final target configuration. The powder can consist essentially of, or consist of, metallic material selected from the group consisting of hafnium, zirconium, molybdenum, rhenium, ruthenium, platinum, tantalum, tungsten and iridium.

In one aspect, the invention includes a component comprising a metallic composition containing metallic molybdenum, metallic hafnium, metallic zirconium, metallic rhenium, metallic ruthenium, metallic tantalum, metallic tungsten, metallic platinum and/or metallic iridium, with the metallic composition containing only a single element or containing more than one element (for example, containing an alloy). The metallic composition is comprised of a plurality of grains. The vast majority of the grains are substantially equiaxial and uniform. The grains can have a grain size of less than or equal to about 30 microns for compositions consisting essentially of molybdenum, less than or equal to about 150 microns for compositions consisting essentially of ruthenium, less than or equal to about 15 microns for compositions consisting essentially of tungsten, and less than or equal to about 50 microns for compositions consisting essentially of iridium.

In one aspect, the invention includes a component comprising a composition consisting of metallic molybdenum, with the metallic molybdenum having an average molybdenum grain size of less than or equal to 25 microns.

In one aspect, the invention includes a physical vapor deposition target consisting of a metallic molybdenum. The target has a sputtering face and has a uniformity of molybdenum grain size and texture such that a sample of the target taken from any location of the face has the same grain size and texture as a sample taken from any other location of the face to within 15% at 1 sigma. The target can also comprise a thickness extending substantially orthogonally to the substantially planar sputtering face. The target can have a uniformity of molybdenum grain size and texture throughout the thickness such that a sample of the target taken from any location of the thickness has the same grain size and texture as a sample taken from any other location of the thickness to within 15% at 1 sigma.

In one aspect, the invention includes a thin film consisting of molybdenum and having a uniformity of less than 0.5% at 1 sigma. Such film can be formed by, for example, physical vapor deposition from a target consisting of metallic molybdenum, with the metallic molybdenum of the target comprising a plurality of grains, substantially all of which are substantially equiaxial, and which have an average grain size of less than or equal to about 25 microns.

### BRIEF DESCRIPTION OF THE DRAWINGS

Preferred embodiments of the invention are described below with reference to the following accompanying drawings.

FIG. 1 is a diagrammatic, cross-sectional view of an exemplary target/backing plate configuration illustrating an exemplary aspect of the present invention.

FIG. 2 is a diagrammatic, top view of a target/backing plate configuration comprising the cross-section of FIG. 1 along the line 1-1.

FIG. 3 is a diagrammatic, cross-sectional view of a preliminary processing stage in accordance with an exemplary methodological aspect of the invention.

FIG. 4 is a diagrammatic, cross-sectional view of a preliminary processing stage in accordance with an exemplary methodological aspect of the invention alternative to that of FIG. 3.

FIG. 5 is a diagrammatic, cross-sectional view of a processing stage subsequent to that of either FIG. 3 or FIG. 4.

FIG. 6 is a diagrammatic, cross-sectional view of an exemplary physical vapor deposition target formed in accordance exemplary aspects of the invention.

### DETAILED DESCRIPTION OF THE PREFERRED EMBODIMENTS

The invention includes methods of forming metallic components having high purity, small grain size, and consistent microstructural uniformity. The metallic components can comprise, consist essentially of, or consist of, for example, one or more of molybdenum, hafnium, zirconium, rhenium, ruthenium, platinum, tantalum, tungsten and iridium. In particular aspects, the metallic components are formed to be physical vapor deposition targets, and are suitable for deposition of highly uniform thin films.

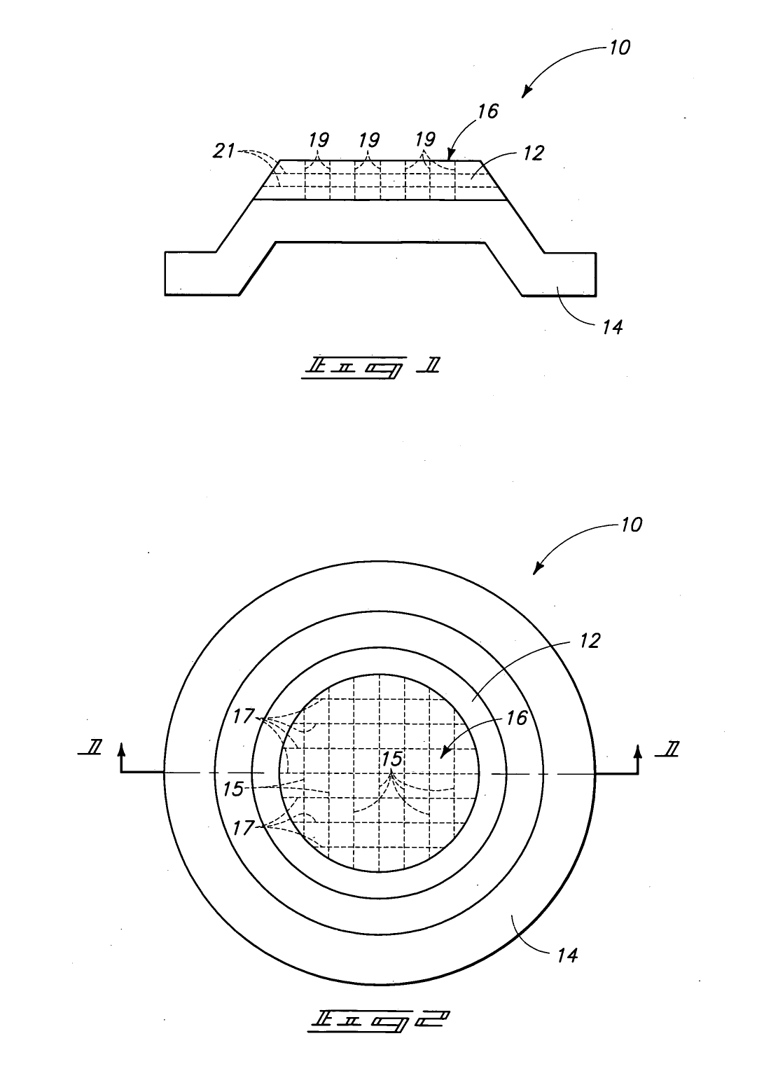

An exemplary physical vapor deposition target construction is described with reference to FIGS. 1 and 2. The construction is shown as part of a target/backing plate assembly 10. Specifically, such assembly comprises a target construction 12 bonded to a backing plate 14. The bond between the target and the backing plate can be any suitable bond, including, for example, a diffusion bond, a solder bond, etc. Also, although not shown, an intermediate layer can be formed between the backing plate and target to enhance the bonding of the target to backing plate.

The target 12 can comprise any of numerous metallic materials, and in particular aspects will comprise, consist essentially of, or consist of, one or more metallic materials selected from the group consisting of metallic molybdenum, metallic hafnium, metallic zirconium, metallic rhenium, metallic ruthenium, metallic tantalum, metallic tungsten, metallic platinum and metallic iridium. The metallic material of the target can be a single element, or can comprise multiple elements (for example, the material can be an alloy of multiple elements).

The backing plate 14 is configured to retain the target in a physical vapor deposition chamber, and can comprise any of numerous materials, including, for example, copper, titanium and/or aluminum. The backing plate can, in some aspects, comprise any of numerous composites, and in some aspects can comprise any of numerous alloys, including, for example, alloys comprising one or more of copper, titanium and aluminum.

The shown configuration of the target/backing plate assembly 10 is but one of numerous configurations known to persons of ordinary skill in the art. Specifically, the shown configuration corresponds to an Applied Materials ENDURA™ configuration, but persons of ordinary skill in the art will recognize that methodology of the present invention can be applied to any target assembly. Also, it is known in the art to sometimes fabricate targets of a configuration such that the target can be directly inserted into a physical vapor deposition chamber, without first forming a target/backing plate assembly. Such targets are referred to in the art as monolithic targets. Methodology of the present invention can be utilized for forming monolithic targets, as well as for forming targets configured to be adhered in target/backing plate assemblies.

The target 12 has a sputtering face 16 from which material is sputtered during a physical vapor deposition process. The sputtering face can be subdivided amongst a plurality of defined locations. For instance, the sputtering face can be subdivided into the grid of FIG. 2 having 60 separate defined locations. The grid has a plurality of vertically-extending dashed lines 15 and a plurality of horizontally-extending dashed lines 17. The dashed lines 15 and 17 are provided in the figure to illustrate the separate defined locations, and would not actually exist across the target face. Grids can be defined to be more coarse or, alternatively, more fine, for various applications, and in some aspects will subdivide the sputtering face into at least 5 separate locations, at least 10 separate locations, or even at least 100 separate locations. A typical application will utilize a nine-point (in other words, nine grid) test.

The invention includes aspects in which the target is formed of a metallic material, and is formed to have sufficient uniformity of grain size and texture such that a sample of the target taken from any of the defined locations of the sputtering face has the same grain size and texture as a sample taken from any other of the defined locations of the face to within 15% at 1 sigma, within 10% at 1 sigma, or to within 5% at 1 sigma. In particular aspects, the sputtering target will consist of metallic molybdenum, and will have the uniformity of grain size and texture such that a sample of the target taken from any defined location of the sputtering face has the same grain size and texture as a sample taken from any other location to within 15% at 1 sigma, within 10% at 1 sigma, or to within 5% at 1 sigma.

FIG. 1 shows the sputtering face 16 having a substantially planar surface. The target can be considered to have a thickness extending substantially orthogonally to the substantially planar surface of the sputtering face. Such thickness can be subdivided amongst a plurality of separate defined locations in a manner analogous to that described for subdivision of a sputtering face amongst a plurality of separate defined locations.

FIG. 1 illustrates a grid comprising vertically-extending dashed lines 19 and horizontally-extending dashed lines 21, with such grid subdividing the thickness of the target into 24 defined locations. The dashed lines are for diagrammatic purposes to illustrate the defined grid, and would not exist on the target. The grid can be of any desired coarseness. In exemplary aspects, the grid will subdivide the target thickness into at least 10 defined locations, at least 20 defined locations, at least 50 defined locations, or even a least 100 defined locations.

In some aspects of the invention, a physical vapor deposition target consists of a metallic material having sufficient uniformity of equiaxed grain size and texture throughout the thickness such that a sample taken from any defined location of the thickness has the same grain size and texture as a sample taken from any other defined location to within 15% at 1 sigma, within 10% at 1 sigma, or to within 5% at 1 sigma. In exemplary aspects, the metallic target material will consist of one or more of molybdenum, hafnium, zirconium, rhenium, ruthenium, platinum, tantalum, tungsten or iridium.

The grains within the metallic material 12 of the target can have an average grain size of less than or equal to about 30 microns, less than or equal to about 20 microns, less than or equal to about 19 microns, or less than or equal to about 15 microns. Smaller grains are desirable, in that smaller grains can lead to deposition of more uniform thin films than do larger grains. It can be desired that not only is the average grain size small, but also that all grains are uniformly small. Accordingly, the invention also includes aspects in which substantially all of the grains have a grain size of less than or equal to about 30 microns, less than or equal to about 20 microns, less than or equal to about 19 microns, or even less than or equal to about 15 microns. The reference to “substantially all” of the grains having the small grain sizes is utilized to indicate that the grains have the small grain size to within errors of detection and measurement. Accordingly, a target in which substantially all of the grains have a grain size of less than or equal to about 30 microns is defined as a target in which all of the grains have the grain size of less than or equal to about 30 microns within errors of detection and measurement.

In particular aspects of the invention, the vast majority of the grains within the target are substantially equiaxial (in other words, the vast majority of the grains are approximately equiaxial, and there is substantially no evidence of deformation structures). An equiaxial grain is a grain having identical dimensions along any cross-section, and accordingly a perfectly equiaxial grain would be a perfect sphere. The grains of the present invention are referred to as being “substantially equiaxial” to indicate that the grains are within 25% of being truly equiaxial. In other words, measurement of a “substantially equiaxial” grain along any axis through a center of the grain yields a dimension that is within 25% of a measurement along any other axis through the center of the grain. The reference that the “vast majority” of the grains are substantially equiaxial indicates that a large percentage of the grains is substantially equiaxial, which in particular aspects can be at least 80% of the grains, at least 90% of the grains, or even at least 99% of the grains. In some aspects, substantially all of the grains are substantially equiaxial; or, in other words, all of the grains are substantially equiaxial to within errors of detection and measurement.

An exemplary method for forming highly uniform metallic materials of the present invention comprises pressing and sintering a very fine powder of metallic material within a uniaxial vacuum hot press. For instance, 325 mesh (i.e. less than 45 micron) metallic powder having a uniform particle size distribution can be subjected to uniaxial vacuum hot pressing to form a high density compact having a shape closely approximating that of the desired shape of a metallic component. If desired, the compact can be subsequently machined to reach the desired shape within high tolerances. The compact is preferably not subjected to any further consolidations after the vacuum hot pressing, and specifically is not subjected to rolling or pressing. In applications in which the metallic material resulting from the vacuum hot pressing is a physical vapor deposition target, such target can be bonded to a backing plate without subjecting the target to rolling or pressing prior to the bonding of the target to the backing plate. The metallic compact resulting from the uniaxial vacuum hot pressing has desired substantially equiaxial grains throughout, and secondary consolidations could anisotropically affect the grains to adversely cause the grains to become less equiaxial.

In an exemplary application of the present invention, a metallic component is formed to consist essentially of, or consist of, molybdenum, and the hot pressing comprises a temperature of at least about 1700° C. and a pressure of at least about 6000 psi for a time of at least about two hours. An exemplary hot press process can comprise the following steps:

initially powder is placed within a chamber and a vacuum within the chamber is pulled down to less than or equal to 10−⁴ Torr (which can reduce oxygen contamination within the final product);

a hydraulic pressure within the vacuum hot press is ramped to about 1250 psi at about 3 Ton/minute (which can pre-compact the powder);

the temperature is ramped to about 850° C. at a rate of about 400° C./hour, and held at such temperature for about 30 minutes (which can remove moisture and allow heat to normalize throughout the die and powder);

a hydraulic pressure is ramped to 4500 psi and held for about 60 minutes (the pressure and heat can start densification);

a temperature is ramped to about 1740° C. at a rate of about 400° C./hour, the pressure is ramped to about 6000 psi, and the pressure and temperature are held for about 3 hours (the high temperature and pressure can densify the compact by reducing the size and/or closing pores); and

the powder is allowed to cool, with compression on the pressed compact/blank being released at about 1300° C., the chamber is backfilled with helium at about 1100° C., and a cooling fan is started.

The densification method of the present invention can not only improve uniformity throughout a metallic component (such as, for example, a PVD target), but also can improve purity of the component. Specifically, the high vacuum utilized during the vacuum hot pressing consolidation can remove various contaminating gasses and low vapor pressure elements (such as, for example, lithium, sodium and potassium).

A density of the metallic component obtained utilizing methodology of the present invention can be at least about 98% of the theoretical maximum density of the metallic material of such component.

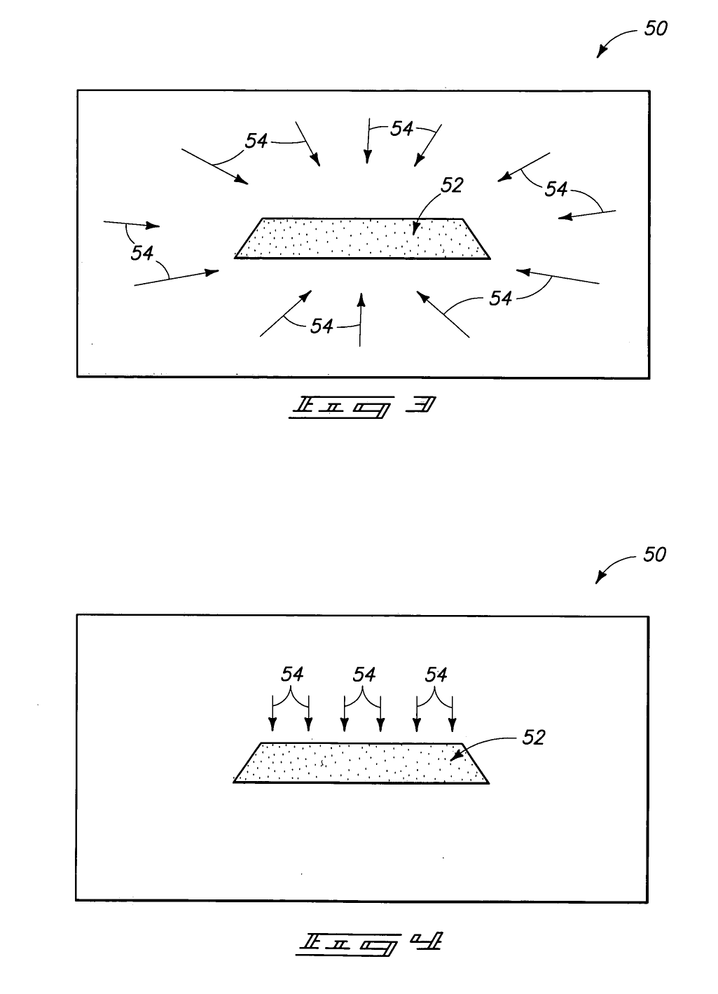

FIGS. 3-5 diagrammatically illustrate exemplary hot isostatic pressing (HIPping) methodology (FIG. 3) and uniaxial vacuum hot pressing methodology (FIG. 4) that can be utilized in accordance with the present invention.

Referring first to FIG. 3, such shows a schematic illustration of an apparatus 50 comprising powder material 52 contained therein. The powder is diagrammatically illustrated with stippling. The powder is subjected to high pressure (represented by arrows 54) and high temperature, with the pressure being provided substantially equally around all sides of the powder, i.e., isostatically. The arrows show pressure only up, down and sideways in the plane of the page, but it is to be understood that pressure would also be applied across the plane of the page so that the pressure is truly around all sides of the powder, i.e., truly isostatic.

FIG. 4 shows an alternative aspect to that of FIG. 3, and shows the apparatus 50 configured to apply the pressure from only one direction, or in other words uniaxially.

The aspects of FIGS. 3 and 4 can be utilized in combination in some aspects of the invention. For instance, in some aspects uniaxial vacuum hot pressing can be followed by HIPping during the consolidation of a metallic powder. The vacuum hot pressing can consolidate the powder to a first degree to form a first consolidated material which is consolidated to the first degree, and the HIPping can consolidate the first consolidated material to a second degree which is greater than the first degree.

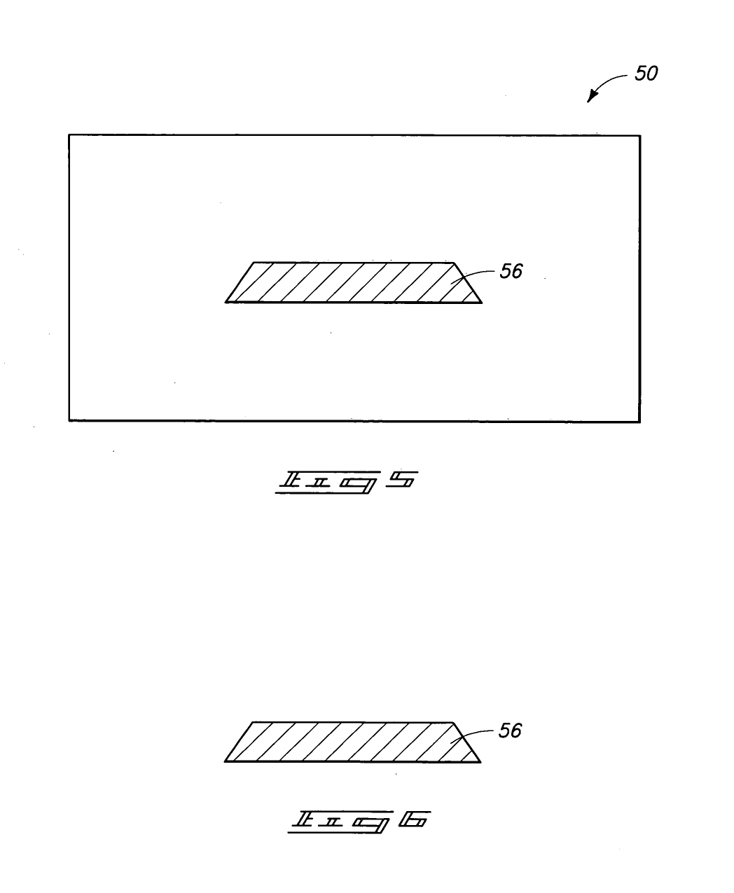

Regardless of whether HIPping is utilized, vacuum hot pressing is utilized, or a combination of HiPping and vacuum hot pressing is utilized, the powder of FIGS. 3 and 4 is consolidated into a metallic component. FIG. 5 shows an exemplary metallic component 56 formed within the apparatus 50 from the metallic material of powder 52 (FIG. 3 or FIG. 4).

FIG. 6 shows the metallic component 56 removed from apparatus 50 (FIG. 5). In the shown aspect of the invention, the metallic component is in the shape of a target blank or perform suitable for bonding to a backing plate. It is to be understood, however, that the metallic component formed in accordance with the methodology of the present invention can have any desired configuration, and accordingly can be utilized for other applications besides PVD targets. The invention can, however, be particularly useful for fabrication of PVD targets, in that the high-uniformity of grain size and texture formed within the target can lead to highly uniform thin films sputter-deposited from the target. For instance, a target consisting essentially of, or consisting of molybdenum formed in accordance with the methodology of the present invention can be utilized to deposit a thin film consisting essentially of, or consisting of, molybdenum, and having a uniformity of less than 0.5% at 1 sigma. The uniformity of the thin film can be determined by various methods known in the art, including, for example, measuring resistance through the thin film. A molybdenum thin film having such high uniformity can be particularly useful for incorporation into acoustic wave resonators and filters.

In some aspects of the invention, PVD components (such as, for example, targets) formed in accordance with processing of the present invention and consisting of one or more of metallic molybdenum, metallic hafnium, metallic zirconium, metallic rhenium, metallic ruthenium, metallic platinum, metallic tantalum, metallic tungsten and metallic iridium can be utilized to form highly uniform thin films for fabrication of integrated circuitry.

The uniformity of grain size and texture throughout the thickness of a target material formed in accordance with aspects of the present invention can enable highly uniform thin films to be consistently produced by the target during the entire lifetime of the target.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

The invention claimed is:

1. A component comprising a metallic composition consisting of one or more materials selected from the group consisting of metallic molybdenum, metallic hafnium, metallic zirconium, metallic rhenium, metallic ruthenium, metallic platinum, metallic tantalum, metallic tungsten and metallic iridium; the metallic composition being comprised of a plurality of grains, the vast majority of the grains being substantially equiaxial, the grains having an average grain size of less than or equal to about 30 microns when the composition comprises metallic molybdenum, less than or equal to about 150 microns when the composition comprises metallic ruthenium, less than or equal to about 15 microns when the composition comprises metallic tungsten, and less than or equal to about 50 microns when the composition comprises metallic hafnium, metallic rhenium, metallic tantalum, metallic zirconium, metallic platinum, or metallic iridium.

2. The component of claim 1 wherein substantially all of the grains are substantially equiaxial.

3. The component of claim 1 wherein the metallic composition comprises metallic molybdenum.

4. The component of claim 1 wherein the metallic composition comprises metallic hafnium.

5. The component of claim 1 wherein the metallic composition comprises metallic zirconium.

6. The component of claim 1 wherein the metallic composition comprises metallic ruthenium.

7. The component of claim 1 wherein the metallic composition comprises metallic iridium.

8. The component of claim 1 being a physical vapor deposition target.

9. The target of claim 8 being part of a target/backing plate assembly.

10. The target of claim 8 being a monolithic target.

11. The component of claim 1 wherein all of the grains of the component have a grain size of less than 30 microns.

12. The component of claim 1 wherein the average grain size is less than 20 microns.

13. The component of claim 1 wherein the average grain size is less than 15 microns.

14. A component comprising a metallic composition comprising molybdenum, the metallic composition having an average molybdenum grain size of less than or equal to 19 microns.

15. The component of claim 14 wherein the metallic composition consists of metallic molybdenum.

16. The component of claim 14 wherein the metallic composition is an alloy comprising metallic molybdenum.

17. The component of claim 14 being a physical vapor deposition target.

18. The target of claim 17 being part of a target/backing plate assembly.

19. The target of claim 17 being a monolithic target.

20. The component of claim 14 wherein substantially all of the molybdenum grains are substantially equiaxial.

21. The component of claim 14 wherein all of the molybdenum grains of the component have a grain size of less than 19 microns.

22. The component of claim 14 wherein the average molybdenum grain size is less than 14 microns.

23. The component of claim 22 wherein all of the molybdenum grains of the component have a grain size of less than 14 microns.

24. A physical vapor deposition target consisting of one or more of metallic molybdenum, metallic hafnium, metallic zirconium, metallic rhenium, metallic ruthenium, metallic platinum, metallic tantalum, metallic tungsten and metallic iridium; the target having a sputtering face and having a uniformity of molybdenum grain size and texture such that a sample of the target taken from any location of the face has the same grain size and texture as a sample taken from any other location of the face to within 15% at 1 sigma.

25. The target of claim 24 wherein the sample of the target taken from any location of the face has the same grain size and texture as the sample taken from any other location of the face to within 10% at 1 sigma.

26. The target of claim 24 wherein the sample of the target taken from any location of the face has the same grain size and texture as the sample taken from any other location of the face to within 5% at 1 sigma.

27. The target of claim 24 consisting of metallic molybdenum.

28. A physical vapor deposition target consisting of one or more of metallic molybdenum, metallic hafnium, metallic zirconium, metallic rhenium, metallic ruthenium, metallic platinum, metallic tantalum, metallic tungsten and metallic iridium; the target having a substantially planar sputtering face and a thickness extending substantially orthogonally to the substantially planar sputtering face; the target having a uniformity of molybdenum grain size and texture throughout the thickness such that a sample of the target taken from any location of has the same grain size and texture as a sample taken from any other location of the target to within 15% at 1 sigma.

29. The target of claim 28 wherein the sample of the target taken from any location has the same grain size and texture as the sample taken from any other location to within 10% at 1 sigma.

30. The target of claim 28 wherein the sample of the target taken from any location has the same grain size and texture as the sample taken from any other location within 5% at 1 sigma.

31. The target of claim 28 consisting of metallic molybdenum.

32. A thin film physical vapor deposited from the target of claim 31, the thin film consisting of molybdenum and having a uniformity of less than 0.5% at 1 sigma.

33. A method of forming a metallic component consisting of a material selected from the group consisting of molybdenum, hafnium, zirconium, ruthenium, platinum, rhenium, tantalum, tungsten and iridium; the method comprising:
providing a powder of the material characterized by being of particle sizes less than or equal to 325 mesh; and
subjecting the powder to uniaxial vacuum hot pressing.

34. The method of claim 33 wherein the hot pressing is conducted at a temperature of at least about 1700° C. and a pressure of at least about 6000 psi for a time of at least about 2 hours.

35. The method of claim 33 wherein the metallic component is a physical vapor deposition target.

36. The method of claim 33 further comprising bonding the target to a backing plate without subjecting the target to rolling or forging prior to the bonding.

37. The method of claim 33 wherein the vacuum hot pressing consolidates the powder to a first degree to form a first consolidated material, and further comprising subjecting said first consolidated material to hot isostatic pressing to consolidate the material to a second degree greater than the first degree.

38. A method of forming a metallic component consisting of a material selected from the group consisting of molybdenum, hafnium, zirconium, ruthenium, platinum, rhenium, tantalum, tungsten and iridium; the method comprising:
providing a powder of the material characterized by being of particle sizes less than or equal to 325 mesh; and
subjecting the powder to hot isostatic pressing.
